(19) United States
(12) Patent Application Publication
(10) Pub. No.: US 2026/0047045 A1
(43) Pub. Date: Feb. 12, 2026

(54) CLOSED INTEGRATED HEAT-DISSIPATION ASSEMBLY STRUCTURE AND LIQUID COOLING MODULE THEREOF

(71) Applicant: Delta Electronics, Inc., Taoyuan City (TW)

(72) Inventors: Chun-Liang Chiang, Taoyuan City (TW); Chih-Wei Yang, Taoyuan City (TW); Hung-Nien Chiu, Taoyuan City (TW); Jhen Ou Yang, Taoyuan City (TW); Tzu-Chao Chiu, Taoyuan City (TW); Chun-Han Wu, Taoyuan City (TW); Cheng-Yuan Wang, Taoyuan City (TW); I-Feng Cheng, Taoyuan City (TW); Wei-Yi Lee, Taoyuan City (TW)

(21) Appl. No.: 19/260,115

(22) Filed: Jul. 3, 2025

Related U.S. Application Data
(60) Provisional application No. 63/679,762, filed on Aug. 6, 2024.

(30) Foreign Application Priority Data
Nov. 18, 2024 (TW) 113212565

(51) Int. Cl. H05K 7/20

(52) U.S. Cl. CPC H05K 7/20272; H05K 7/20254; H05K 7/20409; H05K 7/20927

(57) ABSTRACT

A closed integrated heat-dissipation assembly and a liquid cooling module thereof are disclosed. The heat-dissipation assembly includes a heat sink plate, plural power modules, an accelerator, a flow channel plate, an inlet pipe and an outlet pipe. The heat sink plate includes a top surface, a bottom surface and plural pin fins arranged on the bottom surface. The power modules are directly disposed on the top surface of the heat sink plate. The accelerator is combined with the pin fins to form a cooling flow channel. The flow channel plate is closely assembled with the bottom surface of the heat sink plate. The flow channel plate includes an inlet and an outlet connected to an inflow chamber and an outflow chamber, respectively, and in communication with each other through the cooling flow channel. The inflow pipe and the outflow pipe are connected to the inlet and the outlet respectively.

### CROSS-REFERENCE TO RELATED APPLICATION

This application claims the benefit of U.S. Provisional Application No. 63/679,762 filed on Aug. 6, 2024, and entitled “CLOSED INTEGRATED HEAT-DISSIPATION ASSEMBLY STRUCTURE”. This application claims priority to Taiwan Patent Application No. 113212565, filed on Nov. 18, 2024. The entireties of the above-mentioned patent application are incorporated herein by reference for all purposes.

### FIELD OF THE INVENTION

The present disclosure relates to a heat-dissipation assembly structure, and more particularly to a heat-dissipation assembly structure and a liquid cooling module thereof, which are integrated into a closed one-piece architecture, so that the system design structure is simplified, the occupied volume and the weight are reduced, and the risk of cooling fluid leakage is reduced.

### BACKGROUND OF THE INVENTION

Generally, an electronic device is often combined with a heat-dissipation assembly to dissipate the internal heat. For example, a high-efficiency power module used in the inverter is often accompanied with a lot of heat generated therefrom, and must be combined with a water-cooled heat-dissipation assembly to achieve an effective effect of heat dissipation.

A traction inverter for the vehicle motor usually includes three high-power modules arranged in a line to form an elongated structure, and the liquid cooling module combined therewith is mostly composed of a heat sink plate, a waterproof gasket and a flow channel plate. The cooling fluid enters the heat exchange chamber from the inlet flow channel, then continuously flows through the heat dissipation fins of a plurality of heat sink plates for heat dissipation, and finally leaves through the outlet flow channel. This architecture is designed to be easy to assemble, but each component occupies a larger volume and weighs more. Moreover, after the components are assembled, it is easy to form a large thermal resistance between the components. In addition, the heat sink plate and the flow channel plate still need to be assembled through O-RING, which is more likely to cause the risk of cooling fluid leakage. How to solve the problem of designing the heat-dissipation assembly structure suitable for multiple electronic devices arranged in a long and narrow manner has always been a major subject in the art.

Therefore, there is a need of providing a heat-dissipation assembly structure and a liquid cooling module thereof, which are integrated into a closed one-piece architecture, so as to simplify the system design structure, reduce the occupied volume and the weight, reduce the risk of cooling fluid leakage, and obviate the drawbacks encountered by the prior arts.

### SUMMARY OF THE INVENTION

An object of the present disclosure is to provide a heat-dissipation assembly structure and a liquid cooling module thereof, which are integrated into a closed one-piece architecture, so that the system design structure is simplified, the occupied volume and the weight are reduced, and the risk of cooling fluid leakage is reduced. In the present disclosure, a plurality of power modules are directly welded to the top surface of the heat sink plate, and the interfaces therebetween are bonded with tin solder to effectively reduce the thermal resistance of the contact surface. In addition, the heat sink plate, the accelerator and the flow channel plate are also assembled into one through welding, so that the columnar pin fins of the heat sink plate are combined to form the cooling flow channel, which can effectively reduce the impedance of the cooling fluid and improve the heat dissipation efficiency of the heat-dissipation assembly structure for the plurality of power modules.

Another object of the present disclosure is to provide a closed integrated heat-dissipation assembly structure and a liquid cooling module thereof. For the heat dissipation needs of multiple power modules arranged in one single direction, the power modules and the heat sink plate, the accelerator and the flow channel plate of the liquid cooling modules are assembled through the processes of, such as brazing welding, diffusion welding, friction stir welding, lightning welding, ultrasonic welding, so that an integrated long and narrow structure is formed, the thermal resistance between components is reduced, and the horizontal parallel flow channels are provided. In the present disclosure, the heat sink plate and the accelerator divide the cooling flow channel into multiple manifold chambers which are connected to the columnar pin fins thermally coupled to multiple power modules. The flow channel plate is divided into symmetrical inflow chamber and outflow chamber through a partition wall. Furthermore, by disposing a diversion structure, the cooling fluid entering the inflow chamber is evenly divided into equal portions and then enters the plurality of manifold chambers through a plurality of through holes disposed adjacent to the elongated lateral side. Then, the cooling fluid is converged into the outflow chamber through a plurality of through holes disposed on the opposite elongated lateral side, so as to discharge the cooling fluid out. The plurality of manifold chambers correspond to the plurality of through holes on both elongated lateral sides to form a plurality of transverse flow channels. The plurality of transverse flow channels are connected between the inflow chamber and the outflow chamber in parallel. The cooling fluid flows through a plurality of longitudinal convex strips of the accelerator and has an equal flow rate, so as to dissipate the heat of the plurality of power modules respectively. Since the flow direction of the plurality of transverse flow channels is perpendicular to the extension direction of the elongated lateral sides rather than along the extension direction of the elongated lateral side, a short path design is adopted, so that the transverse flow channels of the plurality of manifold chambers are located between two opposite elongated lateral sides of the elongated housing base. It helps to reduce the length of the flow channels and improve the uniform heat dissipation performance. Thereby, the cooling-flow-channel inlet and the cooling-flow-channel outlet can be disposed at different ends of the elongated lateral side, respectively. Furthermore, the through holes extended along the two opposite elongated lateral sides and the manifold chambers connected therebetween have the same width, and the cooling fluid flowing through the plurality of flow channels formed can be uniformly divided by at least one manifold structure, so that the plurality of electronic devices corresponding to the plurality of manifold chambers in the heat-dissipation assembly structure have similar heat dissipation conditions, which can quickly and evenly take away the heat generated by the plurality of electronic devices. Thus, the overall heat dissipation efficiency is improved effectively.

In accordance with an aspect of the present disclosure, a heat-dissipation assembly structure is provided and includes a heat sink plate, a plurality of power modules, an accelerator, a flow channel plate, an inflow tube and an outflow tube. The heat sink plate includes a top surface, a bottom surface and a plurality of pin fins, wherein the top surface and the bottom surface are two opposite surfaces, and the plurality of pin fins are disposed on the bottom surface. The plurality of power modules are directly disposed on the top surface of the heat sink plate. The accelerator is disposed on the bottom surface of the heat sink plate and combined with the plurality of pin fins to form a cooling flow channel. The flow channel plate is closely assembled with the bottom surface of the heat sink plate, wherein the flow channel plate includes an inlet, an outlet, an inflow chamber and an outflow chamber, wherein the inlet and the outlet are in communication with the inflow chamber and the outflow chamber, respectively, and the inflow chamber and the outflow chamber are in communication with each other through the cooling flow channel. The inflow tube and the outflow tube are connected to the inlet and the outlet, respectively.

In an embodiment, the plurality of power modules are directly disposed on the top surface of the heat sink plate through tin soldering, brazing welding, ultrasonic welding, lightning welding or diffusion welding, wherein the heat sink plate, the accelerator and the flow channel plate are integrated through brazing welding, diffusion welding, friction stir welding, lightning welding or ultrasonic welding.

In an embodiment, the cooling flow channel includes a plurality of manifold chambers disposed between the bottom surface of the heat sink plate and the accelerator, wherein the plurality of manifold chambers are spaced apart along a first direction and thermally coupled to the plurality of power modules through the heat sink plate.

In an embodiment, the heat sink plate and the accelerator are assembled to form a plurality of first through holes and a plurality of second through holes, the plurality of first through holes and the plurality of second through holes are correspondingly disposed at two opposite ends of the plurality of manifold chambers, and the second direction is perpendicular to the first direction, wherein the inflow chamber is in communication with the plurality of manifold chambers through the plurality of first through holes, and the plurality of manifold chambers are in communication with the outflow chamber through the plurality of second through holes.

In an embodiment, the flow channel plate further includes a partition wall, the partition wall is inclined relative to the first direction and the second direction, and an internal space of the flow channel plate is divided into the inflow chamber and the outflow chamber.

In an embodiment, the flow channel plate further includes a diversion structure, which is disposed in the inflow chamber, connected to the partition wall and configured to provide a diversion function for the plurality of first through holes.

In an embodiment, the plurality of first through holes and the plurality of second through holes are slotted holes extended along the first direction, wherein the plurality of manifold chambers, the plurality of first through holes and the plurality of second through holes have an identical width in view of the first direction, wherein the accelerator includes a plurality of longitudinal convex strips extending along the first direction, the plurality of longitudinal convex strips are spatially corresponding to the plurality of pin fins, the plurality of longitudinal convex strips and the plurality of pin fins are connected along a third direction, and the third direction is perpendicular to the first direction and the second direction.

In an embodiment, the plurality of power modules, the heat sink plate, the accelerator and the flow channel plate are stacked and arranged along a third direction through welding to integrally form an elongated structure, and the third direction is perpendicular to the first direction and the second direction, wherein the inlet and the outlet are located adjacent to a pair of short lateral sides of the elongated structure, respectively.

In an embodiment, the inflow tube and the outflow tube are respectively connected to the inlet and the outlet through a quick connector.

In an embodiment, the heat-dissipation assembly structure further includes a plurality of fasteners, wherein the plurality of fasteners are disposed on an outer periphery of the heat sink plate, the accelerator or the flow channel plate, and are configured to fix the heat-dissipation assembly structure to a chassis, and the flow channel plate is attached to the chassis.

In an embodiment, the inflow chamber and the outflow chamber are triangular in shape and symmetrical to each other, wherein the heat sink plate, the accelerator and the flow channel plate are made of a metal material.

In accordance with another aspect of the present disclosure, a liquid cooling module is provided and includes a heat sink plate, an accelerator and a flow channel plate. The heat sink plate includes a top surface, a bottom surface and a plurality of pin fins, wherein the top surface and the bottom surface are two opposite surfaces, and the plurality of pin fins are disposed on the bottom surface, wherein the top surface of the heat sink plate is configured to directly connected with a plurality of power modules directly disposed on the top surface of the heat sink plate to dissipate heat for the plurality of power modules. The accelerator is disposed on the bottom surface of the heat sink plate and combined with the plurality of pin fins to form a cooling flow channel. The flow channel plate is closely assembled with the bottom surface of the heat sink plate, wherein the flow channel plate includes an inlet, an outlet, an inflow chamber and an outflow chamber, wherein the inlet and the outlet are in communication with the inflow chamber and the outflow chamber, respectively, and the inflow chamber and the outflow chamber are in communication with each other through the cooling flow channel, wherein the inlet and the outlet are connected to an inflow tube and an outflow tube for external communication, respectively.

In an embodiment, the heat sink plate, the accelerator and the flow channel plate are made of a metal material, the heat sink plate, the accelerator and the flow channel plate are assembled into one piece through brazing welding, diffusion welding, friction stir welding, lightning welding and ultrasonic welding.

In an embodiment, the plurality of power modules are disposed on the top surface of the heat sink plate, arranged and spaced apart along a first direction, and the cooling flow channel is connected between the inflow chamber and the outflow chamber along a second direction, wherein the first direction is perpendicular to the second direction.

In an embodiment, the plurality of power modules, the heat sink plate, the accelerator and the flow channel plate are stacked and arranged along a third direction through welding to form an integrated elongated structure, and the third direction is perpendicular to the first direction and the second direction.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a perspective structural view illustrating a heat-dissipation assembly structure according to a first embodiment of the present disclosure;

FIG. 2 and FIG. 3 are exploded views illustrating the heat-dissipation assembly structure according to the first embodiment of the present disclosure;

FIG. 4 is a schematic diagram showing the flow direction of the cooling fluid in the inflow chamber and the outflow chamber according to the first embodiment of the present disclosure;

FIG. 5 is a schematic diagram showing the flow direction of the cooling fluid in the cooling channel according to the first embodiment of the present disclosure; and

FIG. 6 is a cross-section view illustrating a heat-dissipation assembly structure according to a second embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “upper,” “lower,” “top,” “bottom,” “front,” “rear” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments.

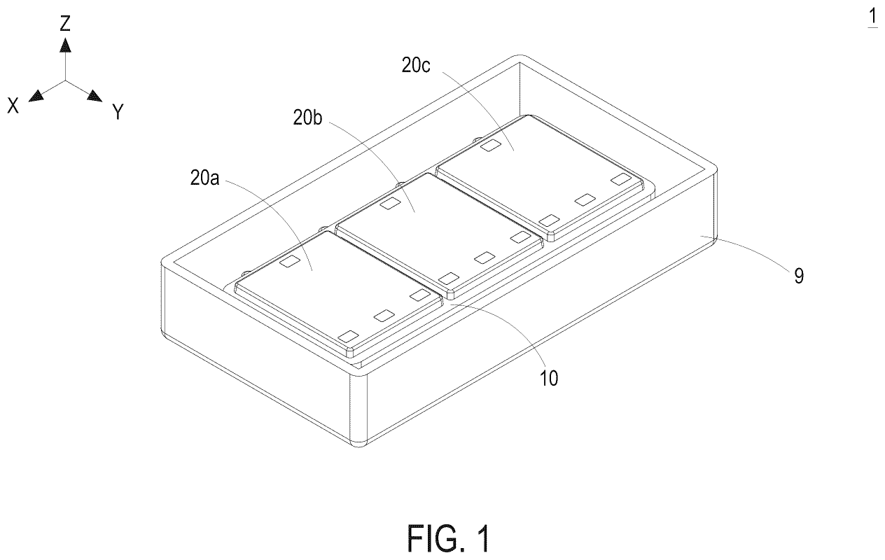

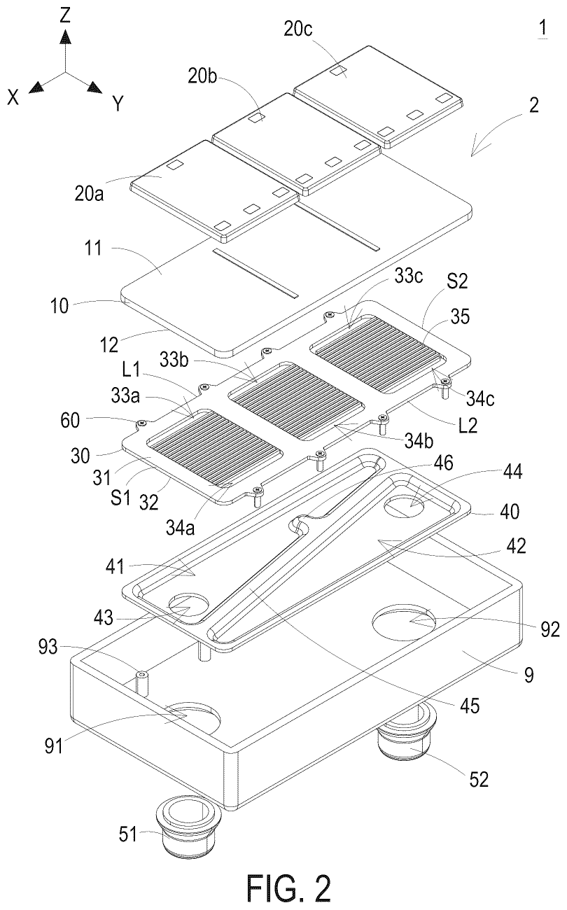

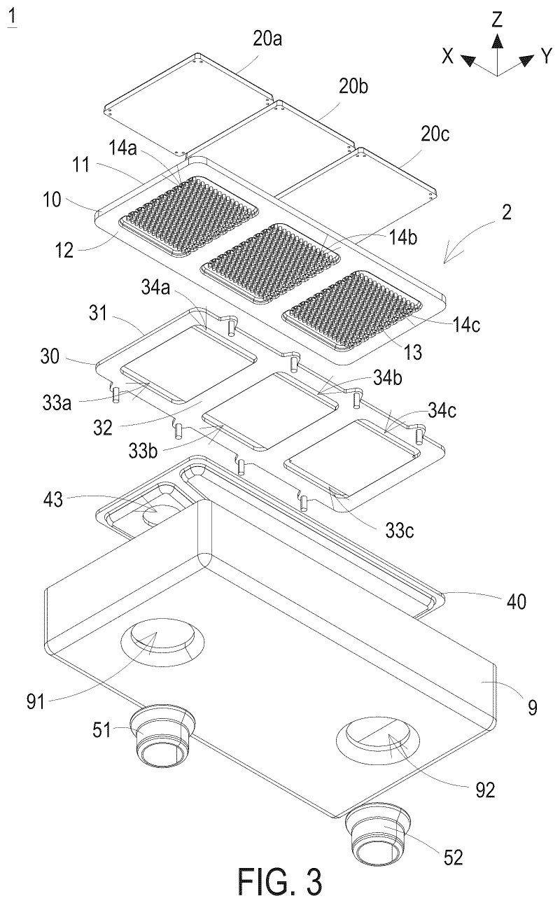

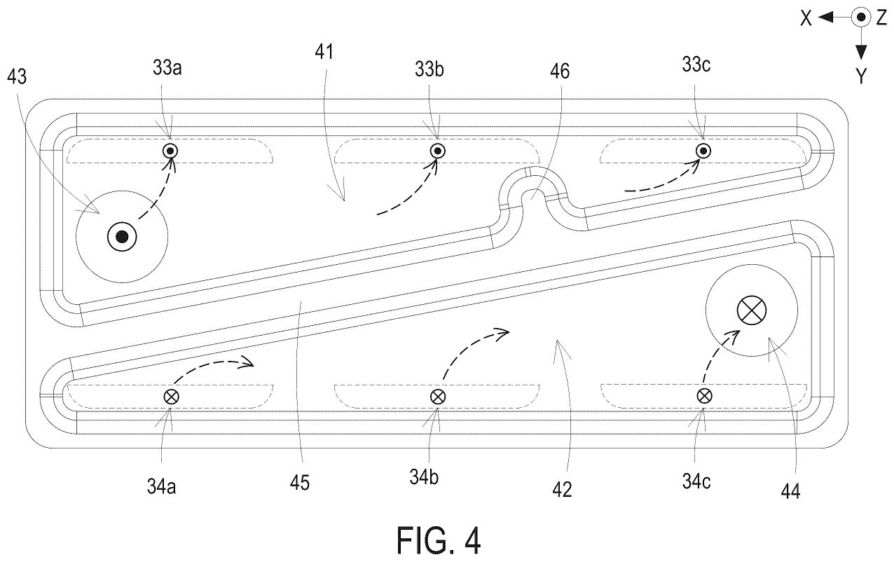

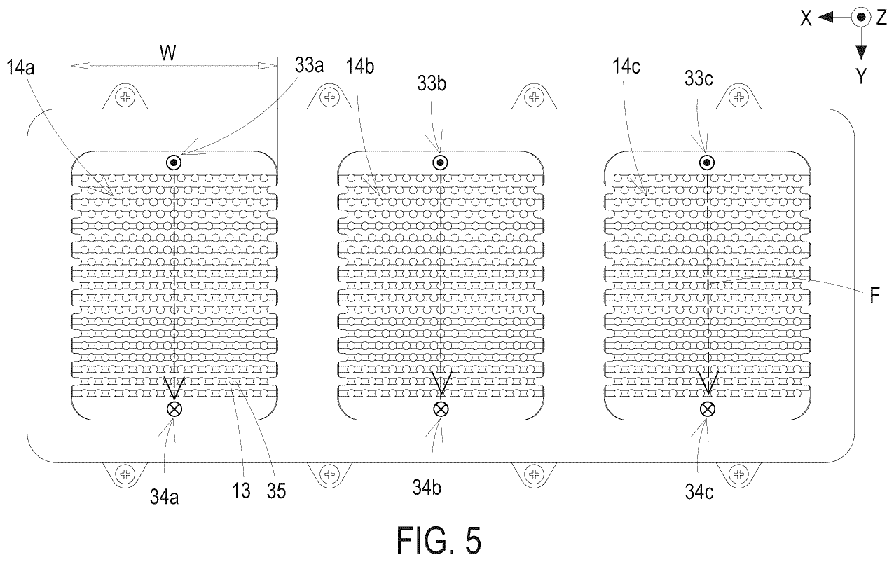

FIG. 1 is a perspective structural view illustrating a heat-dissipation assembly structure according to a first embodiment of the present disclosure. FIG. 2 and FIG. 3 are exploded views illustrating the heat-dissipation assembly structure according to the first embodiment of the present disclosure. FIG. 4 is a schematic diagram showing the flow direction of the cooling fluid in the inflow chamber and the outflow chamber according to the first embodiment of the present disclosure. FIG. 5 is a schematic diagram showing the flow direction of the cooling fluid in the cooling channel according to the first embodiment of the present disclosure. Please refer to FIGS. 1 to 5. In the embodiment, the present disclosure provides a closed integrated heat-dissipation assembly structure used in inverters. The heat-dissipation assembly structure 1 includes a heat sink plate 10, a plurality of power modules 20a, 20b, 20c, an accelerator 30, a flow channel plate 40, an inflow tube 51 and an outflow tube 52. The heat sink plate 10 includes a top surface 11, a bottom surface 12 and a plurality of pin fins 13. The top surface 11 and the bottom surface 12 are two opposite surfaces. The plurality of pin fins 13 are disposed on the bottom surface 12. The plurality of power modules 20a, 20b, 20c are arranged at intervals along a first direction (i.e., the X axial direction), and directly disposed on the top surface 11 of the heat sink plate 10 through tin soldering, brazing welding, ultrasonic welding, lightning welding or diffusion welding. Since the interface between the power modules 20a, 20b, 20c and the heat sink plate 10 is bonded with tin solder, the thermal resistance value of the contact surface is sufficiently reduced. In the embodiment, the accelerator 30 is disposed on the bottom surface 12 of the heat sink plate 10 and combined with the plurality of pin fins 13 to form a cooling flow channel. Preferably but not exclusively, the bottom surface 12 of the heat sink plate 10 and the top surface 31 of the accelerator 30 are assembled into one piece through brazing, diffusion welding, friction stir welding, lightning welding, or ultrasonic welding, and the formed cooling flow channel includes a plurality of manifold chambers 14a, 14b, 14c disposed between the bottom surface 12 of the heat sink plate 10 and the accelerator 30. In the embodiment, the plurality of manifold chambers 14a, 14b, 14c are spaced apart along the first direction (i.e., the X axial direction) and thermally coupled to the plurality of power modules 20a, 20b, 20c through the heat sink plate 10. Preferably but not exclusively, in other embodiments, the accelerator 30 is embedded in the bottom surface 12 of the heat sink plate 10 and partially connected to the plurality of pin fins 13 to form the plurality of manifold chambers 14a, 14b, 14c. The present disclosure is not limited thereto. In the embodiment, the flow channel plate 40 is closely assembled with the bottom surface 32 of the accelerator 30, and further closely assembled with the bottom surface 12 of the heat sink plate 10 through the top surface 31 of the accelerator 30. In other embodiments, the accelerator 30 is embedded in the bottom surface 12 of the heat sink plate 10, and the flow channel plate 40 is directly and closely assembled with the periphery of the bottom surface 12 of the heat sink plate 10. Notably, the heat sink plate 10, the accelerator 30 and the flow channel plate 40 are made of a metal material, the heat sink plate 10, the accelerator 30 and the flow channel plate 40 are assembled into one piece through brazing welding, diffusion welding, friction stir welding, lightning welding and ultrasonic welding. In that, an elongated structure of liquid cooling module 2 is integrally formed, and includes a pair of long lateral sides L1, L2 opposite to each other, and a pair of short lateral sides S1, S2 opposite to each other.

In the embodiment, the flow channel plate 40 includes an inlet 43, an outlet 44, an inflow chamber 41 and an outflow chamber 42. The inlet 43 and the outlet 44 are in communication with the inflow chamber 41 and the outflow chamber 42, respectively, and the inflow chamber 41 and the outflow chamber 42 are in communication with each other through the plurality of manifold chambers 14a, 14b, 14c of the cooling flow channel. The inflow tube 51 and the outflow tube 52 are connected to the inlet 43 and the outlet 44, respectively. Notably, in the embodiment, the heat sink plate 10 and the accelerator 30 are assembled to form a plurality of first through holes33a, 33b, 33c and a plurality of second through holes 34a, 34b, 34c. Preferably but not exclusively, the plurality of first through holes 33a, 33b, 33c and the plurality of second through holes 34a, 34b, 34c are slotted holes extended along the first direction (i.e., the X axial direction). In the embodiment, the plurality of first through holes 33a, 33b, 33c are disposed adjacent to the long lateral side L1 and arranged at intervals along the first direction (i.e., the X axial direction). The plurality of second through holes 34a, 34b, 34c are disposed adjacent to the long lateral side L2 and arranged at intervals along the first direction (i.e., the X axial direction). In the embodiment, the plurality of first through holes 33a, 33b, 33c and the plurality of second through holes 34a, 34b, 34c are correspondingly disposed at two opposite ends of the plurality of manifold chambers 14a, 14b, 14c in a second direction (i.e., the Y axial direction), and the second direction is perpendicular to the first direction. In the embodiment, the inflow chamber 41 is in communication with the plurality of manifold chambers 14a, 14b, 14c through the plurality of first through holes 33a, 33b, 33c, and the plurality of manifold chambers 14a, 14b, 14c are in communication with the outflow chamber 42 through the plurality of second through holes 34a, 34b, 34c.

Furthermore, in the embodiment, the accelerator 30 further includes a plurality of longitudinal convex strips 35 extending along the first direction (i.e., the X axial direction). The plurality of longitudinal convex strips 35 are spaced apart from each other in the second direction (i.e., the Y axial direction), and spatially corresponding to the plurality of pin fins 13 disposed on the bottom surface 12 of the heat sink plate 10. In the embodiment, the heat sink plate 10, the accelerator 30 and the flow channel plate 40 are stacked and arranged along a third direction (i.e., the Z axial direction) through welding to form an integrated elongated structure of the liquid cooling module 2, and the third direction is perpendicular to the first direction and the second direction. Preferably but not exclusively, in the embodiment, the plurality of longitudinal convex strips 35 and the plurality of pin fins 13 are connected along the third direction (i.e., the Z axial direction), so as to form the plurality of manifold chambers 14a, 14b, 14c with fluid acceleration function.

Notably, in the embodiment, the plurality of manifold chambers 14a, 14b, 14c, the plurality of first through holes 33a, 33b, 33c, and the plurality of second through holes 34a, 34b, 34c are all equal in number and are all three. The manifold chamber 14a, the first through hole 33a and the second through hole 34a are corresponding to form a flow channel F1. The manifold chamber 14b, the first through hole 33b and the second through hole 34b are corresponding to form a flow channel F2. The manifold chamber 14c, the first through hole 33c and the second through hole 34c are corresponding to form a flow channel F3. Three flow channels F1, F2, F3 are connected in parallel between the inflow chamber 41 and the outflow chamber 42, and the flow directions of the three flow channels F1, F2, F3 are perpendicular to the first direction (i.e., the X axial direction) and parallel to Y axial direction. Certainly, the present disclosure is not limited thereto.

In the embodiment, the flow channel plate 40 further includes a partition wall 45. The partition wall 45 is inclined relative to the first direction (i.e., the X axial direction) and the second direction (i.e., the Y axial direction), and an internal space of the flow channel plate 40 is divided into the inflow chamber 41 and the outflow chamber 42. Through the arrangement of the partition wall 45, the inflow chamber 41 and the outflow chamber 42 are triangular in shape and symmetrical to each other. In the embodiment, the inlet 43 is disposed adjacent to the short lateral side S1 of the elongated structure, and the outlet 44 is disposed adjacent to the short lateral side S2 of the elongated structure. Thereby, the inlet 43 and the outlet 44 are arranged approximately along the first direction (i.e., the X axial direction) on the elongated structure. Certainly, the present disclosure is not limited thereto.

In the embodiment, the flow channel plate 4 further includes a diversion structure 46, which is disposed in the inflow chamber 41. One end of the diversion structure 46 is connected to the partition wall 45, and the other end of the diversion structure 46 is protruded along the second direction (i.e., the Y axial direction). Thereby, the diversion structure 46 provides the diversion function for the plurality of first through holes 33a, 33b, 33c. It allows the parallel flow channels F1, F2, F3 to achieve a uniform flow rate and meet the heat dissipation requirements of the plurality of power modules 20a, 20b, 20c arranged in one single direction. Certainly, in other embodiments, the diversion structure 46 is disposed in the outflow chamber 42 and configured to provide a diversion function for the plurality of second through holes 34a, 34b, 34c. The present disclosure is not limited thereto.

In the embodiment, the heat-dissipation assembly structure 1 is applied to the inverter. For the heat dissipation needs of the plurality of power modules 20a, 20b, 20c arranged in one single direction, the plurality of power modules 20a, 20b, 20c and the heat sink plate 10, the accelerator 30 and the flow channel plate 40 of the liquid cooling modules 2 are assembled through the processes of, such as brazing welding, diffusion welding, friction stir welding, lightning welding, ultrasonic welding, so that an integrated long and narrow structure is formed, the thermal resistance between components is reduced, and the horizontal parallel flow channels are provided. The power modules 20a, 20b, 20c and the liquid cooling module 2 of the heat-dissipation assembly structure 1 are further built on the inverter chassis. In the embodiment, the heat-dissipation assembly structure 1 further includes a plurality of fasteners 60. The plurality of fasteners 60 are disposed on an outer periphery of the accelerator 30 of the liquid cooling module 2. In addition, the chassis 9 includes a plurality of mounting posts 93 spatially corresponding to the plurality of fasteners 60. By engaging the fasteners 60 with the corresponding mounting posts 93, the liquid cooling module 2 of the heat-dissipation assembly structure 1 is fixed to the chassis 9, so that the bottom of the flow channel plate 40 is attached to the chassis 9. On the other hand, the chassis 9 further includes two openings 91, 92, which are spatially corresponding to the inlet 43 and the outlet 44 on the flow channel plate 40, respectively. Thereby, the inflow tube 51 and the outflow tube 52 can be connected to the inflow 43 and the outlet 44 along the third direction (i.e., the Z axial direction) through a quick connector, respectively. Certainly, the direction in which the inlet tube 51 and the outlet tube 52 connect the inlet 43 and the outlet 44 is not limited thereto.

Preferably but not exclusively, in the embodiment, the plurality of power modules 20a, 20b, 20c are three power devices used in a multi-phase inverter and configured to output the driving current of the motor. Since each power device needs to have its own input and output electrical connections, it needs to be arranged in a single direction and electrically connected to the outside on both elongated lateral sides L1, L2 of the heat-dissipation assembly structure 1. In order to meet the heat dissipation requirements of the plurality of power modules 20a, 20b, 20c arranged in one single direction, the heat-dissipation assembly structure 1 has the plurality of power modules 20a, 20b, 20c disposed on the top surface 11 of the heat sink plate 10, arranged along the first direction (i.e., the X axial direction), and thermally coupled to the plurality of pin fins 13. In case of that the plurality of power modules 20a, 20b, 20c are served as the power devices of the aforementioned multi-phase inverter, the power modules 20a, 20b, 20c can be electrically connected to the outside via the two long lateral sides L1, L2. Certainly, the present disclosure is not limited thereto.

In the embodiment, after a cooling fluid (not shown) is introduced into the inflow chamber 41 through the outflow tube 52 and the inlet 43, the cooling fluid is evenly divided into the plurality of first through holes 33a, 33b, 33c through the diversion function of the diversion structure 46 in the inflow chamber 41, and enters the plurality of manifold chambers 14a, 14b,14c, respectively. The cooling fluid in the plurality of manifold chambers 14a, 14b, 14c is acted upon by the plurality of longitudinal convex strips 35 of the accelerator 30 and conducts heat exchange with the plurality of pin pins 13 to dissipate heat from the plurality of power modules 20a, 20b, 20c. Thereafter, the cooling fluid in the plurality of manifold chambers 14a, 14b, 14c flows to the outflow chamber 42 through the confluence in the plurality of second through holes 34a, 34b, 34c respectively. Finally, the cooling fluid is discharged out of the outflow chamber 42 through the outlet 44 and the outflow tube 52.

In the embodiment, the plurality of manifold chambers 14a, 14b, 14c correspond to the first through holes 33a, 33b, 33c adjacent to the first lateral side L1, and correspond to the second through holes 34a, 34b, 34c adjacent to the second lateral side L2 along the second direction (i.e., the Y axial direction), so that a plurality of transverse flow channels F1, F2, F3 are formed. Through the designs of the inflow chamber 41, the outflow chamber 42 and the diversion structure 46, the plurality of transverse flow channels F1, F2, F3 are connected in parallel between the inflow chamber 41 and the outflow chamber 42. In that, the cooling fluid with equal flow rate is evenly divided to dissipate the heat from the plurality of power modules 20a, 20b, 20c, respectively. Notably, the flow direction of the plurality of transverse flow channels F1, F2, F3 is perpendicular to the elongated lateral sides, that is, the extended direction of the long lateral sides L1, L2. The flow direction is not designed to extend along the long lateral sides L1, L2, but is designed in a short path, so that the cooling fluid flows through the transverse flow channels F1, F2, F3 of the plurality of manifold chambers 14a, 14b, 14c in the shortest path of the liquid cooling module 2. It helps to reduce the length of the flow channels and improve the uniform heat dissipation performance. In this way, the inlet 43 and the outlet 44 can be arranged adjacent to the two short lateral sides S1, S2, respectively to provide the cooling fluid in and out. In the embodiment, the plurality of first through holes 33a, 33b, 33c and the plurality of second through holes 34a, 34b, 34c are all slotted holes, which are extended along the first direction (i.e., the X axial direction). Moreover, the plurality of first through holes 33a, 33b, 33c, the plurality of second through holes 34a, 34b, 34c and the plurality of manifold chambers 14b, 14c have an identical width W in view of the first direction. The plurality of flow channels F1, F2, F3 are formed to achieve the even diversion, so that the plurality of power modules 20a, 20b, 20c corresponding to the plurality of manifold chambers 14a, 14b, 14c in the heat-dissipation assembly structure 1 have similar heat dissipation conditions, which can quickly and evenly take away the heat generated by the plurality of power modules 20a, 20b, 20c. Thus, the overall heat dissipation efficiency is improved effectively.

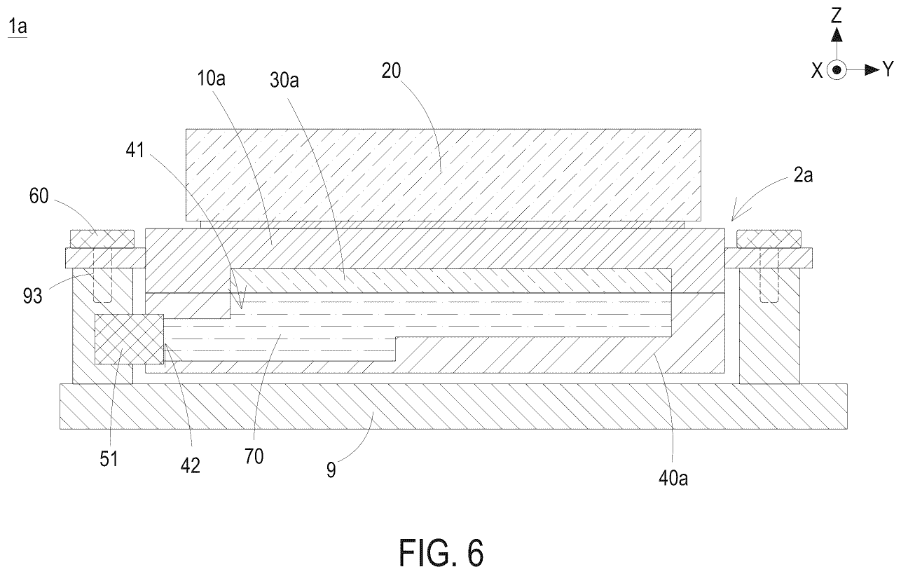

FIG. 6 is a cross-section view illustrating a heat-dissipation assembly structure according to a second embodiment of the present disclosure. In the embodiment, the structures, elements and functions of the heat-dissipation assembly structure 1a and the liquid cooling module 2a are similar to those of the heat-dissipation assembly structure 1 and the liquid cooling module 2 of FIGS. 1 to 5, and are not redundantly described herein. Please refer to FIG. 4, FIG. 5 and FIG. 6. In the embodiment, the power module 20 is welded to the top surface 11 of the heat sink plate 10 through the solder 21. The accelerator 30a is embedded in the bottom surface 12 of the heat sink plate 10a by welding. In that, a plurality of manifold chambers 14a, 14b, 14c, a plurality of first through holes 33a, 33b, 33c and a plurality of second through holes 34a, 34b, 34c are formed as shown in FIG. 5. The number and the size of the manifold chambers 14a, 14b, 14c, the first through holes 33a, 33b, 33c and the second through holes 34a, 34b, 34c, the size, the type and the arrangement of the pin fins 13 and the longitudinal convex strips 35 are adjustable according to the practical requirements, and the present disclosure is not limited thereto. Preferably but not exclusively, the accelerator 30a and the heat sink plate 10a are welded to form the parallel flow channels F1, F2, F3 with a uniform flow to meet the heat dissipation requirements of the plurality of power modules 20 arranged in one single direction. Then, the bottom surface 12 of the heat sink plate 10a is connected to the flow channel plate 40a by welding to form an inlet 43, an outlet 44, an inflow chamber 41 and an outflow chamber 42 as shown in FIG. 4. Certainly, the size, the shape and the arrangement of the inlet 43, the outlet 44, the inflow chamber 41 and the outflow chamber 42 are adjustable according to the practical requirements, and the present disclosure is not limited thereto. Furthermore, in the embodiment, the opening direction of the inlet 43 is not limited to facing the third direction (i.e., the Z axial direction). Preferably but not exclusively, as shown in FIG. 6, the opening direction of the inlet 43 is toward the second direction (i.e., the Y axial direction). According to the opening direction of the inlet 43, the inflow tube 51 can be connected to the inlet 43 in the second direction through a quick connector. Certainly, the flow path of the liquid cooling module 2a that guides the cooling fluid 70 to the cooling flow channel is adjustable according to the practical requirements, and the present disclosure is not limited thereto. It should be emphasized that, the power module 20, the heat sink plate 10a, the accelerator 30a and the flow channel plate 40a of the present disclosure are assembled by welding to achieve the closed integrated heat-dissipation assembly structure 1a including the power module 20 and the liquid cooling module 2a. Preferably but not exclusively, the liquid cooling module 2a is fixed to the chassis 9 by engaging the fastener 60 with the corresponding mounting post 93. The welding order and the welding method of the power module 20, the heat sink plate 10a, the accelerator 30a and the flow channel plate 40a, and the assembling method with the chassis 9 can be combined and adjustable according to the practical requirements. The present disclosure is not limited thereto and not redundantly described hereafter.

In summary, the present disclosure provides a heat-dissipation assembly structure and a liquid cooling module thereof, which are integrated into a closed one-piece architecture, so that the system design structure is simplified, the occupied volume and the weight are reduced, and the risk of cooling fluid leakage is reduced. In the present disclosure, a plurality of power modules are directly welded to the top surface of the heat sink plate, and the interfaces therebetween are bonded with tin solder to effectively reduce the thermal resistance of the contact surface. In addition, the heat sink plate, the accelerator and the flow channel plate are also assembled into one through welding, so that the columnar pin fins of the heat sink plate are combined to form the cooling flow channel, which can effectively reduce the impedance of the cooling fluid and improve the heat dissipation efficiency of the heat-dissipation assembly structure for the plurality of power modules. For the heat dissipation needs of multiple power modules arranged in one single direction, the power modules and the heat sink plate, the accelerator and the flow channel plate of the liquid cooling modules are assembled through the processes of, such as brazing welding, diffusion welding, friction stir welding, lightning welding, ultrasonic welding, so that an integrated long and narrow structure is formed, the thermal resistance between components is reduced, and the horizontal parallel flow channels are provided. In the present disclosure, the heat sink plate and the accelerator divide the cooling flow channel into multiple manifold chambers which are connected to the columnar pin fins thermally coupled to multiple power modules. The flow channel plate is divided into symmetrical inflow chamber and outflow chamber through a partition wall. Furthermore, by disposing a diversion structure, the cooling fluid entering the inflow chamber is evenly divided into equal portions and then enters the plurality of manifold chambers through a plurality of through holes disposed adjacent to the elongated lateral side. Then, the cooling fluid is converged into the outflow chamber through a plurality of through holes disposed on the opposite elongated lateral side, so as to discharge the cooling fluid out. The plurality of manifold chambers correspond to the plurality of through holes on both elongated lateral sides to form a plurality of transverse flow channels. The plurality of transverse flow channels are connected between the inflow chamber and the outflow chamber in parallel. The cooling fluid flows through a plurality of longitudinal convex strips of the accelerator and has an equal flow rate, so as to dissipate the heat of the plurality of power modules respectively. Since the flow direction of the plurality of transverse flow channels is perpendicular to the extension direction of the elongated lateral sides rather than along the extension direction of the elongated lateral side, a short path design is adopted, so that the transverse flow channels of the plurality of manifold chambers are located between two opposite elongated lateral sides of the elongated housing base. It helps to reduce the length of the flow channels and improve the uniform heat dissipation performance. Thereby, the cooling-flow-channel inlet and the cooling-flow-channel outlet can be disposed at different ends of the elongated lateral side, respectively. Furthermore, the through holes extended along the two opposite elongated lateral sides and the manifold chambers connected therebetween have the same width, and the cooling fluid flowing through the plurality of flow channels formed can be uniformly divided by at least one manifold structure, so that the plurality of electronic devices corresponding to the plurality of manifold chambers in the heat-dissipation assembly structure have similar heat dissipation conditions, which can quickly and evenly take away the heat generated by the plurality of electronic devices. Thus, the overall heat dissipation efficiency is improved effectively.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A heat-dissipation assembly structure, comprising:
a heat sink plate comprising a top surface, a bottom surface and a plurality of pin fins, wherein the top surface and the bottom surface are two opposite surfaces, and the plurality of pin fins are disposed on the bottom surface;
a plurality of power modules directly disposed on the top surface of the heat sink plate;
an accelerator disposed on the bottom surface of the heat sink plate and combined with the plurality of pin fins to form a cooling flow channel;
a flow channel plate closely assembled with the bottom surface of the heat sink plate, wherein the flow channel plate comprises an inlet, an outlet, an inflow chamber and an outflow chamber, wherein the inlet and the outlet are in communication with the inflow chamber and the outflow chamber, respectively, and the inflow chamber and the outflow chamber are in communication with each other through the cooling flow channel; and
an inflow tube and an outflow tube connected to the inlet and the outlet, respectively.

2. The heat-dissipation assembly structure according to claim 1, wherein the plurality of power modules are directly disposed on the top surface of the heat sink plate through tin soldering, brazing welding, ultrasonic welding, lightning welding or diffusion welding, wherein the heat sink plate, the accelerator and the flow channel plate are integrated through brazing welding, diffusion welding, friction stir welding, lightning welding or ultrasonic welding.

3. The heat-dissipation assembly structure according to claim 1, wherein the cooling flow channel comprises a plurality of manifold chambers disposed between the bottom surface of the heat sink plate and the accelerator, wherein the plurality of manifold chambers are spaced apart along a first direction and thermally coupled to the plurality of power modules through the heat sink plate.

4. The heat-dissipation assembly structure according to claim 3, wherein the heat sink plate and the accelerator are assembled to form a plurality of first through holes and a plurality of second through holes, the plurality of first through holes and the plurality of second through holes are correspondingly disposed at two opposite ends of the plurality of manifold chambers, and the second direction is perpendicular to the first direction, wherein the inflow chamber is in communication with the plurality of manifold chambers through the plurality of first through holes, and the plurality of manifold chambers are in communication with the outflow chamber through the plurality of second through holes.

5. The heat-dissipation assembly structure according to claim 4, wherein the flow channel plate further comprises a partition wall, the partition wall is inclined relative to the first direction and the second direction, and an internal space of the flow channel plate is divided into the inflow chamber and the outflow chamber.

6. The heat-dissipation assembly structure according to claim 5, wherein the flow channel plate further comprises a diversion structure, which is disposed in the inflow chamber, connected to the partition wall and configured to provide a diversion function for the plurality of first through holes.

7. The heat-dissipation assembly structure according to claim 4, wherein the plurality of first through holes and the plurality of second through holes are slotted holes extended along the first direction, wherein the plurality of manifold chambers, the plurality of first through holes and the plurality of second through holes have an identical width in view of the first direction, wherein the accelerator comprises a plurality of longitudinal convex strips extending along the first direction, the plurality of longitudinal convex strips are spatially corresponding to the plurality of pin fins, the plurality of longitudinal convex strips and the plurality of pin fins are connected along a third direction, and the third direction is perpendicular to the first direction and the second direction.

8. The heat-dissipation assembly structure according to claim 4, wherein the plurality of power modules, the heat sink plate, the accelerator and the flow channel plate are stacked and arranged along a third direction through welding to integrally form an elongated structure, and the third direction is perpendicular to the first direction and the second direction, wherein the inlet and the outlet are located adjacent to a pair of short lateral sides of the elongated structure, respectively.

9. The heat-dissipation assembly structure according to claim 1, wherein the inflow tube and the outflow tube are respectively connected to the inlet and the outlet through a quick connector.

10. The heat-dissipation assembly structure according to claim 1, further comprising a plurality of fasteners, wherein the plurality of fasteners are disposed on an outer periphery of the heat sink plate, the accelerator or the flow channel plate, and are configured to fix the heat-dissipation assembly structure to a chassis, and the flow channel plate is attached to the chassis.

11. The heat-dissipation assembly structure according to claim 1, wherein the inflow chamber and the outflow chamber are triangular in shape and symmetrical to each other, wherein the heat sink plate, the accelerator and the flow channel plate are made of a metal material.

12. A liquid cooling module, comprising:
a heat sink plate comprising a top surface, a bottom surface and a plurality of pin fins, wherein the top surface and the bottom surface are two opposite surfaces, and the plurality of pin fins are disposed on the bottom surface, wherein the top surface of the heat sink plate is configured to directly connected with a plurality of power modules directly disposed on the top surface of the heat sink plate to dissipate heat for the plurality of power modules;
an accelerator disposed on the bottom surface of the heat sink plate and combined with the plurality of pin fins to form a cooling flow channel; and
a flow channel plate closely assembled with the bottom surface of the heat sink plate, wherein the flow channel plate comprises an inlet, an outlet, an inflow chamber and an outflow chamber, wherein the inlet and the outlet are in communication with the inflow chamber and the outflow chamber, respectively, and the inflow chamber and the outflow chamber are in communication with each other through the cooling flow channel, wherein the inlet and the outlet are connected to an inflow tube and an outflow tube, respectively for external communication.

13. The liquid cooling module according to claim 12, wherein the heat sink plate, the accelerator and the flow channel plate are made of a metal material, the heat sink plate, the accelerator and the flow channel plate are assembled into one piece through brazing welding, diffusion welding, friction stir welding, lightning welding and ultrasonic welding.

14. The liquid cooling module according to claim 12, wherein the plurality of power modules are disposed on the top surface of the heat sink plate, arranged and spaced apart along a first direction, and the cooling flow channel is connected between the inflow chamber and the outflow chamber along a second direction, wherein the first direction is perpendicular to the second direction, wherein the plurality of power modules, the heat sink plate, the accelerator and the flow channel plate are stacked and arranged along a third direction through welding to form an integrated elongated structure, and the third direction is perpendicular to the first direction and the second direction.
